(19) United States
(12) Patent Application Publication
(10) Pub. No.: US 2002/0197749 A1
(43) Pub. Date: Dec. 26, 2002

(54) Method of monitoring and controlling a photoresist edge bead

(75) Inventors: Dennis Knight, South Wales (GB); Andrew Naylor, Newport (GB); Rachel Watkins, MonMouthshire (GB); Derek Stanley, Gwent (GB)

Correspondence Address: GEORGE O. SAILE, 20 MCINTOSH DRIVE, POUGHKEEPSIE, NY, 12603, US

(73) Assignee: European Semiconductor Manufacturing Limited

(21) Appl. No.: 09/898,388

(22) Filed: Jul. 5, 2001

(30) Foreign Application Priority Data
Jun. 21, 2001 (GB) 0115259.4

(51) Int. Cl. H01L 21/66; G01R 31/26; H01L 21/302; H01L 21/461; H01L 21/31; H01L 21/469

(52) U.S. Cl. 438/14; 438/725; 438/948; 438/780

(57) ABSTRACT

A process, and structure, used to monitor and control the level of photoresist removed at the periphery of a photoresist coated, semiconductor substrate, has been developed. A monitoring structure comprised of a group of graduated scribe marks, laser formed near the periphery of the semiconductor, monitoring substrate, is included with product semiconductor substrates, during the application of a photoresist layer, and during the photoresist edge bead removal procedure. The width of the photoresist edge bead, removed from product semiconductor substrates is determined via examination of the monitoring semiconductor substrate, in terms of measuring the level of graduated scribe marks, now exposed. This measurement determines the status of the product semiconductor substrates, in regards to continued processing, or rework.

### BACKGROUND OF THE INVENTION

(1) Field of the Invention

The present invention relates to methods used to form photoresist shapes on a semiconductor substrate, and more specifically to a method used to measure the width of photoresist layer removed at the periphery of the semiconductor substrate, prior to use of the photoresist shape as a masking layer.

(2) Description of Prior Art

Micro-miniaturization, or the ability to fabricate semiconductor devices with sub-micron features, has been realized via advances in specific semiconductor fabrication disciplines, such as photolithography. The use of more sophisticated exposure cameras, as well as the development of more sensitive photoresist materials, have allowed sub-micron images to be routinely formed in photoresist shapes. In turn, advances in dry etching procedures have allowed the sub-micron images, in masking photoresist shapes, to be transferred to underlying materials used as building blocks of sub-micron, semiconductor devices.

Photoresist shapes, used as a mask for definition of underlying materials, are employed numerous times during the fabrication of semiconductor devices. For example photoresist shapes can be used as mask to allow patterning, or etching of an underlying metal layer, to create a metal interconnect structure for the sub-micron, semiconductor device. In addition a photoresist layer may be used as a protective layer during a dicing procedure, used to divide a finished semiconductor substrate into individual dies or chips. However the application of a photoresist layer can result in edge bead formation, or formation of a thickened photoresist component, located at the edge, or periphery of the semiconductor substrate. The photoresist edge bead can interfere with subsequent processing procedures, such as clamping of the semiconductor substrate to a component of a dry etching tool, resulting in poor physical and electrical contact to a plasma type etching tool, possibly resulting in decreased dry etching success, not allowing the sub-micron images in the masking photoresist shape to be transferred to the underlying material. Therefore edge bead removal procedures, such the use of discharging a solvent at the periphery of the semiconductor substrate, during a spin cycle, has been used to remove photoresist from the periphery of the semiconductor substrate.

The amount of photoresist edge bead removal needed however is dependent on the specific application the photoresist layer is being used for. Again for use as a mask for definition in a dry etch tool, the width of the removed photoresist should be sufficient to allow a clamping procedure to be accomplished on a photoresist free surface, while removal of a narrower photoresist edge bead region is needed when the photoresist shape or layer, is used for a protective layer for dicing operations. Removal of a wider photoresist edge bead may uncover, and therefore not protect, dies, or chips located near the periphery of the semiconductor substrate, during a dicing operation. This invention will describe a process for monitoring and controlling the amount of photoresist edge bead removed. A test vehicle, comprised of a semiconductor wafer with specific graduations, is processed, or coated with photoresist, along with the product semiconductor wafers. After an edge bead removal step, the monitor wafer is examined to determine if the proper amount of edge bead removal had been accomplished for that specific photoresist application. The monitoring procedure can be followed by a photoresist rework procedure for the product semiconductor substrates if the removal of photoresist edge bead, on the monitor wafer, was unsatisfactory.

Therefore this invention will provide a method of monitoring and controlling the width of photoresist edge beads, as well as describing a structure used for quantitative evaluation of photoresist edge bead width. Prior art, such as Nguyen et al, in U.S. Pat. No. 6,057,206, as well as Jones et al, in U.S. Pat. No. 6,117,778, show photoresist shapes with peripheral edge beads removed, however these prior arts do not show the method used, and monitoring vehicle employed, in this present invention, used to quantitatively measure, or monitor, the width of the removed photoresist edge bead.

### SUMMARY OF THE INVENTION

It is an object of this invention to provide a method for monitoring the width of photoresist edge bead removed.

It is another object of this invention to provide a test vehicle, featuring readable engraved scribed marks located at specific distances from the periphery of a semiconductor substrate, to allow a quantitative measure of the extent of photoresist edge bead removal to be performed.

In accordance with the present invention a method of monitoring and controlling the width of photoresist edge bead removed at the periphery of a photoresist semiconductor substrate, as well as the test vehicle used for quantitative evaluation of the width of the photoresist edge bead removed, is described. A semiconductor substrate, used for monitoring purposes only, is prepared with sets of laser scribe marks, formed to a specific depth in the substrate and with each specific scribe mark placed, and identified, at a specific distance from the periphery of the monitoring substrate. The monitoring substrate along with the product semiconductor substrates are coated with a photoresist layer, and then prior to exposure and development procedures, subsequently to be performed to the photoresist layer on the product semiconductor substrates, are subjected to a procedure used to remove photoresist from the periphery of the substrates. The width of the removed photoresist edge bead is then determined via observance of the uncovered scribe mark on the monitoring semiconductor substrate, nearest the edge of the remaining photoresist layer. Rework, stripping and recoating of photoresist, is performed on both product and monitoring semiconductor substrates, if the width of the measured photoresist edge bead removed was not acceptable.

### BRIEF DESCRIPTION OF THE DRAWINGS

The object and advantages of this invention are best described in the preferred embodiment with reference to the attached drawings that include:

FIGS. 1-2, which schematically show a top view of a monitoring semiconductor substrate, featuring scribe marks placed at specific distances from the periphery of the semiconductor substrate, which allow a quantitative measurement of the width of removed photoresist edge bead to be determined.

FIG. 3, which schematically in cross-sectional style, shows the scribe marks in the monitor semiconductor substrate, specifically showing the width of photoresist edge bead removed via observance of the specific, uncovered scribe mark, closest to the photoresist layer.

### DESCRIPTION OF THE PREFERRED EMBODIMENTS

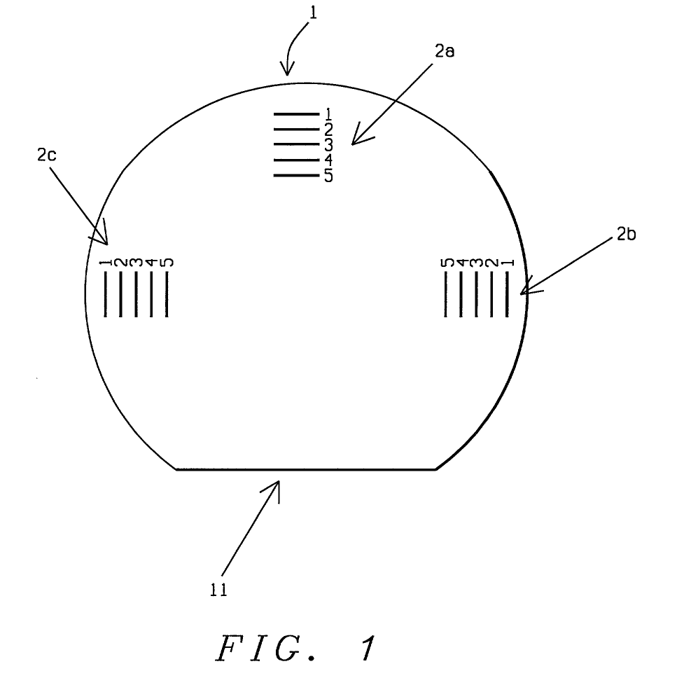

The process used to monitor and control the width of photoresist edge bead removed at the periphery of a photoresist semiconductor substrate, as well as the test vehicle used for quantitative evaluation of the width of the photoresist edge bead removed, will now be described in detail. A semiconductor substrate 1, to be used only for monitoring the extent, or width, of the photoresist edge bead removed, is described, and schematically shown in FIGS. 1-2. Three sets of scribe marks, 2a, 2b, and 2c, are formed in semiconductor substrate 1, at three positions, with set 2a, directly opposite semiconductor flat 11, and with set 2b, and 2c, placed +90° and −90°, from set 2a. This is shown schematically in FIG. 1.

Each set of scribe marks is formed via laser procedures, to a depth in semiconductor substrate 1, between about 2 to 3 um. Each set is comprised of five laser scribed marks, with each mark comprised at a width 8, of about 0.11 mm. Width 7, identifying the space between scribe marks, in a specific set, is between about 0.75 to 1.25 mm. Space 6, between about 0.75 to 1.25 mm, identifies the distance or space between the scribe mark closest to the periphery of semiconductor substrate 1, and the periphery of semiconductor substrate 1. Each mark is also numbered, via laser scribing, with the mark closest to the periphery scribed number 1, and with the mark furthest from the periphery labelled number 5. Length 5, comprised of the length of each scribe mark, including the length of scribed identifying number, is between about 3.75 to 4.25 mm. These features are schematically shown for set 2a, in FIG. 2. The features of the scribed marks, regarding depth, width, space, etc, are designed to allow observation of a specific mark, uncovered as a result of the photoresist edge bead removal procedure, with the specific mark allowing a quantitative evaluation of the width of the edge bead removal to be established.

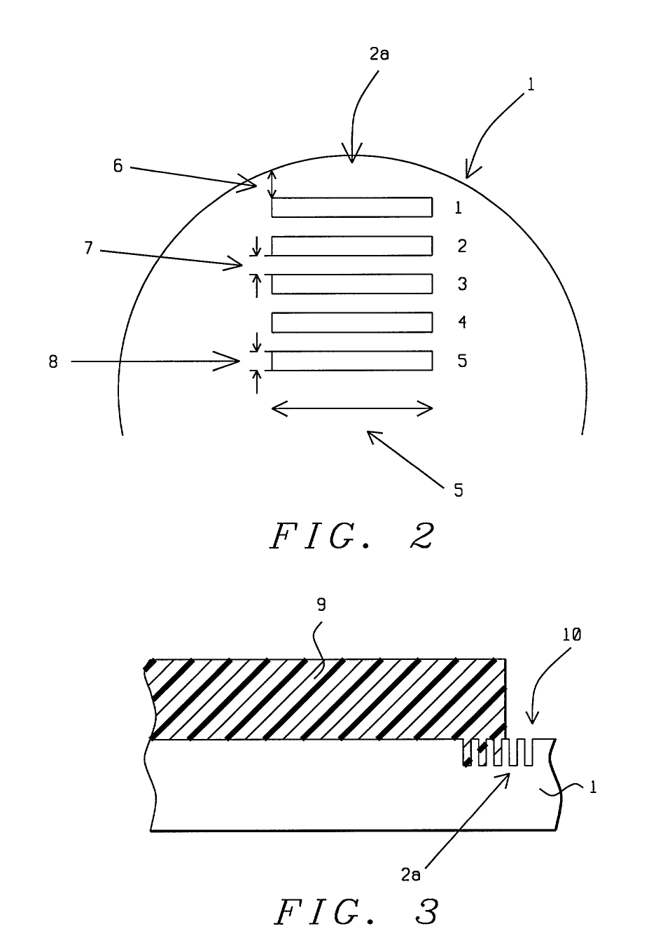

The method of performing the removal of, the monitoring of, and the controlling of, a photoresist edge bead, is now detailed, and described schematically in FIG. 3. Product semiconductor substrates, those substrates comprised of numerous, identical pieces, or chips, which in turn are comprised with defined electronic circuitry, in addition to monitor semiconductor substrate 1, are coated with photoresist layer 9, at a thickness between about 0.5 to 7.0 um, via conventional photoresist application procedures. A solvent, such as 2-methoxy-1-methylethyl acetate is then ejected from a solvent nozzle, directed at the portion of photoresist layer 9, located near the periphery of semiconductor substrate 1, as well directed at the same location for the product semiconductor substrates. The amount of solvent ejected, as well as the location on photoresist layer 9, in which the solvent is being ejected on, is dependent on the desired width of photoresist layer 9, to be removed. The success of the photoresist edge bead removal procedure is next evaluated using monitoring semiconductor substrate 1. Region 10, of monitoring semiconductor substrate 1, indicates the exposed portion of scribe mark, set 2a, where for this example the width of the removed photoresist edge bead extends from the periphery of semiconductor substrate 1, to a location between scribe mark 2 and scribe mark 3, corresponding to a removed portion of between about 2 to 3 mm. The observance of the location of exposed scribe marks is accomplished via the naked eye, however only for monitoring semiconductor substrate 1. Therefore if the reading of the width of the removed edge bead is acceptable, the product semiconductor substrates experiencing the identical photoresist edge bead removal procedure can continue to be processed without subjection to possible contamination occurring during examination of the width of the photoresist edge bead. However if the width of the removed portion of photoresist edge bead is not correct, the product semiconductor, as well as monitoring semiconductor substrate 1, can be reworked, regarding stripping of the photoresist layer, followed by re-application, edge bead removal, and monitoring of the removal width. The use of the monitoring semiconductor substrate allows a quantitative assessment of the width of the removed photoresist edge bead, allowing specific removed widths to be obtained for specific photolithographic steps. For example for a first case a wider, removed region is needed to allow increased contact between the substrate and a clamp used in a dry etching tool, in contrast to a second case in which only a narrow photoresist edge bead needs to be removed.

The use of a monitor wafer to determine the width of the edge bead removal procedure does not have to be implemented with every product job. For example a monitor wafer can be used at specific frequencies, for example once a day, or once for every four product jobs, to monitor photolithographic procedures, or to qualify a specific photolithographic tool. In addition the use of scribe marks to determine the extent of edge bead removal can also be accomplished via use of scribe marks on product wafers. A mark can be formed on the product wafer to show a maximum acceptable limit of the width of the edge band removal. For example if a product's maximum acceptable edge bead removal width is 2 mm, then only a scribe mark at 2 mm from the product wafer edge will be used at one or more locations around the periphery of the wafer. If the product requires both a minimum and maximum limit, regarding edge bead removal width, then two scribe marks, formed at specific locations around the periphery of the product wafer are employed.

While this invention has been particularly shown and described with reference to, the preferred embodiments thereof, it will be understood by those skilled in the art that various changes in form and details may be made without departing from the spirit and scope of this invention.

What is claimed is:

1. A method of monitoring the width of a portion of photoresist layer removed from the periphery of a substrate during a photoresist edge bead removal procedure, comprising the steps of:
preparing a monitoring substrate comprised with sets of scribe marks, with all scribe marks formed to a specific width and formed at a specific depth in said monitoring substrate, and with a specific space located between said scribe marks, with each set of scribe marks spaced at a specific distance from periphery of said monitoring substrate;
applying a photoresist layer on said monitoring substrate, and on product substrates, wherein said product substrates are comprised with elements of integrated circuitry;
performing a photoresist edge bead removal procedure to remove a portion of said photoresist layer from the periphery of said monitor substrate, and performing said photoresist edge bead removal procedure to said product substrates, removing a portion of said photoresist layer from the periphery of said product substrate, with said portion of photoresist layer removed from said product substrate equal in width to said portion of said photoresist layer removed from said monitoring substrate; and
measuring the width of the removed portion of said photoresist layer on said monitor substrate.

2. The method of claim 1, wherein said monitoring substrate is a silicon semiconductor substrate, such as a non-product monitor wafer, or the monitoring substrate can be the product wafer, comprised with the needed scribe marks.

3. The method of claim 1, wherein said scribe marks are formed in said monitoring substrate via laser procedures.

4. The method of claim 1, wherein said depth of said scribe marks, formed in said monitoring substrate, is between about 2.0 to 3.0 um.

5. The method of claim 1, wherein each set of scribe marks, formed in said monitoring substrate via laser procedures, are comprised of five, individual scribe marks, each with a width of about 0.11 mm, and with a space between said scribe marks of between about 0.75 to 1.25 mm.

6. The method of claim 1, wherein said photoresist edge bead removal procedure is performed using 2-methoxy-1-methylethyl acetate as a solvent.

7. The method of claim 1, wherein said width of said removed portion of photoresist edge bead is measured via non-microscopic procedures, the naked eye.

8. A method of monitoring and controlling the width of a portion of a photoresist layer removed from the periphery of product semiconductor substrates during a photoresist edge bead removal procedure, via use of a monitoring procedure applied to a portion of a photoresist layer removed from the periphery of a monitoring semiconductor substrate, comprising the steps of:
performing a laser procedure to form sets of scribe marks in said monitoring semiconductor substrate, wherein each set of scribe marks is comprised of individual scribe marks formed to a specific width and to a specific depth in said monitoring semiconductor substrate, with specific spaces located between scribe marks, and with each set of scribe marks spaced at a specific distance from periphery of said monitoring substrate;
applying a photoresist layer on said monitoring semiconductor substrate, and on said product semiconductor substrates, wherein said product semiconductor substrates may be comprised with elements of integrated circuitry;
performing a photoresist edge bead removal procedure to remove a portion of said photoresist layer from the periphery of said product semiconductor substrates, and removing a portion of said photoresist layer from the periphery of said monitoring semiconductor substrate, exposing a portion of scribe marks;
measuring width of portion of said photoresist layer removed from said monitoring semiconductor substrate during said photoresist edge bead removal procedure, via determining the distance of exposed scribe mark from the periphery of said monitoring semiconductor substrate; and
determining if a rework procedure is needed for said photoresist layer located on said product semiconductor substrates, via evaluation of said measurement of width of said portion of photoresist layer removed from said monitoring semiconductor substrate, during said photoresist edge bead removal procedure.

9.The method of claim 8, wherein said monitoring semiconductor substrate is a silicon semiconductor substrate, such as a non-product monitor wafer, or the monitoring substrate can be the product wafer, comprised with the needed scribe marks.

10. The method of claim 8, wherein said depth of said scribe marks, formed in said monitoring semiconductor substrate, is between about 2.0 to 3.0 um.

11. The method of claim 8, wherein each set of scribe marks, formed in said monitoring semiconductor substrate, are comprised of five, individual scribe marks, with each individual scribe mark comprised with a width of about 0.11 mm, and with a space between about 0.75 to 1.25 mm, between individual scribe marks.

12. The method of claim 8, wherein said photoresist edge bead removal procedure is performed using 2-methoxy-1-methylethyl acetate as a solvent.

13. The method of claim 8, wherein the width of the portion of photoresist edge bead removed is measured via use of the naked eye.

14. A monitoring semiconductor substrate, comprising:
a silicon substrate;
three sets of scribe marks located at a specific distance from periphery of said silicon substrate, with a second set of scribe marks located 90° to the left of a first set of scribe marks, while a third set of scribe marks is located 90° to the right of said first set of scribe marks;
each set of scribe marks comprised of five individual scribe marks, with a number mark, between 1-5, formed adjacent to a corresponding scribe mark;
each individual scribe mark at a specific depth in said semiconductor substrate;
each individual scribe mark at a specific width;
each individual scribe mark comprised at a specific length; and
a specific space between each individual scribe mark.

15. The monitoring semiconductor substrate of claim 14, wherein said silicon substrate can be a non-product, monitor silicon wafer, or said silicon substrate can be a product silicon wafer, comprised with monitoring scribe marks.

16. The monitoring semiconductor substrate of claim 14, wherein the specific distance of each set of scribe marks from the periphery of said silicon substrate is between about 0.75 to 1.25 mm.

17. The monitoring semiconductor substrate of claim 14, wherein the depth of each individual scribe mark, in said silicon substrate, is between about 2.0 to 3.0 um.

18. The monitoring semiconductor substrate of claim 14, wherein the specific width of each individual scribe mark is about 0.11 mm.

19. The monitoring semiconductor substrate of claim 14, wherein the specific length of each individual scribe mark, including the adjacent number mark, is between about 3.75 to 4.25 mm.

20. The monitoring semiconductor substrate of claim 14, wherein the specific space between individual scribe marks is between about 0.75 to 1.25 mm.
